(19) United States
(12) Patent Application Publication
(10) Pub. No.: US 2003/0222263 A1
(43) Pub. Date: Dec. 4, 2003

(54) High-efficiency light-emitting diodes

(75) Inventor: Hong K. Choi, Sharon, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kopin Corporation, Taunton, MA

(21) Appl. No.: 10/163,099

(22) Filed: Jun. 4, 2002

(51) Int. Cl. H01L 27/15

(52) U.S. Cl. 257/79

(57) ABSTRACT

Light-emitting diodes (LEDs) have at least one light-emitting surface that is patterned, thereby improving the ratio of internal to external efficiency. In one embodiment, the light-emitting diodes are gallium nitride based group III-V diodes that have a multiple quantum-well active region between an n-doped GaN layer and a p-doped GaN layer. The n-doped GaN layer has a surface that is patterned.

### BACKGROUND OF THE INVENTION

High-efficiency light-emitting diodes (LEDs) are desired for many applications such as displays, printers, short-haul communications, optoelectronic computer interconnects. However, there is a significant gap between the internal efficiency of LEDs and their external efficiency. The internal quantum yield of a good-quality diode can exceed 99%. However, external efficiency is less than 30% and typically is as low as 2%. The reason for the difference in the internal and external efficiency of LEDs is that light generated internally in the semiconductor material of the diode must pass through the interface between the semiconductor and air, for example, or another optically transmissive medium, such as an optically transmissive epoxy resin. Light is both refracted and internally reflected at the interface according to Snell's Law. At a critical angle (θ_{c}), and at any angle larger than the critical angle, light traveling through a medium having a higher refractive index and striking an interface with a medium having a lower refractive index will be totally internally reflected. The critical angle is dependent on the refractive index of the two media and is given by the following formula:

sin θ_{c}=η₂/η₁

wherein:

η₁ is the refractive index of the higher refractive index material.

η₂ is the refractive index of the lower refractive index material.

As can be seen from the above formula, the critical angle becomes smaller when there is a large difference between the refractive index of the two materials forming the interface, such as in the case of a semiconductor/air interface. The smaller the critical angle, the more light is internally reflected rather than transmitted through the interface. Multiple internal reflections result in reabsorption of a large percentage of photons generated within the semiconductor material.

One method that has been used to reduce this problem is to shape the entire light-emitting surface into a spherical dome. This increases the probability that a photon generated inside the semiconductor material will strike the interface at an angle smaller than the critical angle. However, fabrication of a large spherical dome is difficult and expensive to manufacture because it requires deep etching. Therefore, a need exists for improved photon extraction from LEDs which both improves the external efficiency of LEDs and reduces the cost of manufacture.

### SUMMARY OF THE INVENTION

The present invention is a light-emitting diode having at least one patterned surface that emits light. The pattern on the light-emitting surface improves photon extraction from the semiconductor material of the diode.

In one embodiment, the light-emitting diode has an n-doped semiconductor layer in contact with a p-doped semiconductor layer and at least one patterned light-emitting surface. Alternatively, the n-doped semiconductor layer and a p-doped semiconductor layer of the diode are separated by an active region. In this embodiment, the active region has a first surface in contact with a first surface of the n-doped semiconductor layer and a second surface in contact with a first surface of the p-doped semiconductor layer. The active region can include, for example, a material that has a lower band-gap energy and higher refractive index than the n-doped and p-doped semiconductor layers. Alternatively, the active region can consist of a single quantum-well layer and two surrounding barrier layers in which the barrier material has a band-gap energy larger than the quantum-well layer but equal to or smaller than the n-doped and p-doped semiconductor layers. The active region can also include multiple quantum-well layers and multiple barrier layers alternately stacked. The patterned surface is a surface of the n-doped semiconductor layer or a surface of the p-doped semiconductor layer. Alternatively, the light-emitting diode has a transparent substrate having first and second surfaces. The first surface of the transparent substrate is in contact with a surface of the n-doped semiconductor layer or a surface of the p-doped semiconductor layer, and the second surface of the transparent substrate is the patterned light-emitting surface. Preferred transparent substrates are formed of GaAs, InP and GaN.

In another embodiment, the light-emitting diode has an n-doped InₓGa₁₋ₓN layer and a p-doped InₓGa₁₋ₓN layer on a silicon substrate, wherein 0≦×≦1. A first surface of the n-doped InₓGa₁₋ₓN layer emits light and is patterned. A first surface of the p-doped InₓGa₁₋ₓN layer is in contact with a second surface of the n-doped InₓGa₁₋ₓN layer. A second surface of the p-doped InₓGa₁₋ₓN layer is coated with an ohmic contact, which can include one or more layers. The ohmic contact is bound to a substrate, such as silicon, germanium, gallium arsenide or a metal, with a conducting layer, such as PdIn₃. In one embodiment, the ohmic contact layer is coated with a reflective layer, such as a metallic layer, and the reflective layer is bound to the substrate with a conducting layer.

In another embodiment, the light-emitting diode has an n-doped GaN layer and a p-doped GaN layer which are separated by a multiple-quantum-well active region composed of multiple InₓGa₁₋ₓN well layers and multiple In_{y}Ga_{1-y}N barrier layers that are alternately stacked, wherein y<x, 0<x≦1, and 0≦y≦1. A first surface of the n-doped GaN layer emits light and is patterned. The active region is between the n-doped GaN layer and the p-doped GaN layer. Preferably, a second surface of the n-doped GaN layer is in contact with a first surface of the active region, and a second surface of the active region is in contact with a first surface of the p-doped GaN layer. Optionally, a second surface of the p-doped GaN layer is coated with the ohmic contact layers and light reflecting layers, which are bound to a silicon substrate or metal with a conducting layer such as PdIn₃.

The patterned surface of the LEDs of the invention are, preferably, patterned as an array of hemispherical, pyramidal, or hexagonal pyramidal (i.e., pyramidal structures having a hexagonal base) surface structures. Typically, the diameters of the base of the hemispherical structures or the diagonals of the pyramidal or hexagonal pyramidal structures are about 0.5 μm to about 20 μm.

As with other electronic devices, there exists a demand for more efficient LEDs, and in particular, LEDs that will operate at higher intensity while using less power. Higher intensity LEDs, for example, are particularly useful for displays or status indicators in various high ambient light environments. High efficiency LEDs with lower power consumption, for example, are particularly useful in various portable electronic equipment applications. In particular, there is a demand for efficient LEDs that will emit light in the green, blue and ultraviolet regions of the visible spectrum (e.g., efficient III-V nitride LED). Blue and green LEDs composed of III-V nitrides typically show a forward current of 20 mA and a forward voltage of 3.4 V to 3.6 V which are higher by about 2 V or more than those of red LEDs made of GaAlAs semiconductors. Therefore, more efficient blue and green LEDs would be desirable.

The gap between the internal and external efficiency of LEDs of the invention having a patterned light-emitting surface generally is less than that of an LED having a planar light-emitting surface because the patterned surface allows more opportunity for internally generated light to strike the interface between the semiconductor and an optically transmissive medium, such as air, at an angle less than the critical angle than does a planar light-emitting surface. Since light striking the interface at an angle which is less than the critical angle will be transmitted instead of internally reflected, less light that is internally generated by the LED is reflected back into the semiconductor layers an reabsorbed. In addition, deep etching of the light-emitting surface is not required because creation of a pattern, such as an array of individual hemispherical or pyramidal structures, does not require shaping of the entire light-emitting surface. Thus, the cost of manufacture of LEDs of the invention is relatively low.

### BRIEF DESCRIPTION OF THE DRAWINGS

FIG. 1 shows the processing steps to obtain an LED with a hemispherical surface structure: a) the photoresist is patterned by a standard photolithography step; b) the photoresist is baked at a high temperature to form rounded edges; and c) the semiconductor is etched using the photoresist mask with an anisotropic etching technique to form a hemispherical surface structure.

FIG. 2 is a cross-sectional representation of one embodiment of a composite LED of the invention.

FIG. 3 is a schematic representation of steps of one method of making the diodes of the invention.

FIG. 4 is a plan view of a light-emitting surface of an LED of the invention having a patterned array of hemispherical structures.

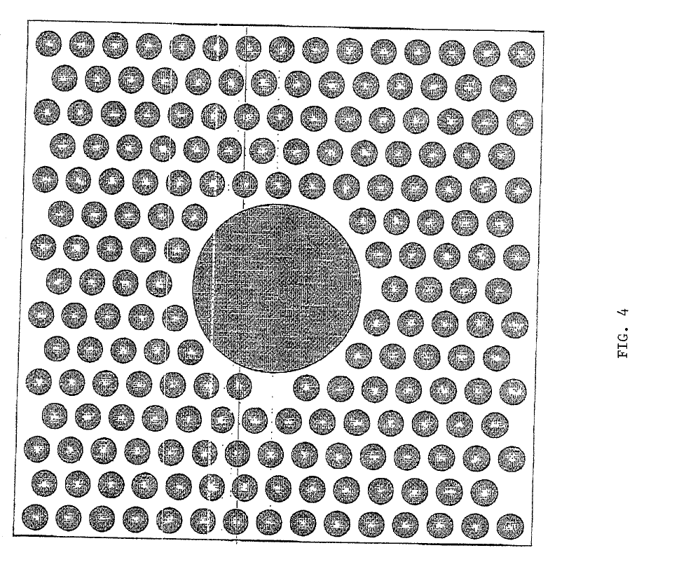

FIG. 5 is a plan view of a light-emitting surface of an LED of the invention having a patterned array of pyramidal structures.

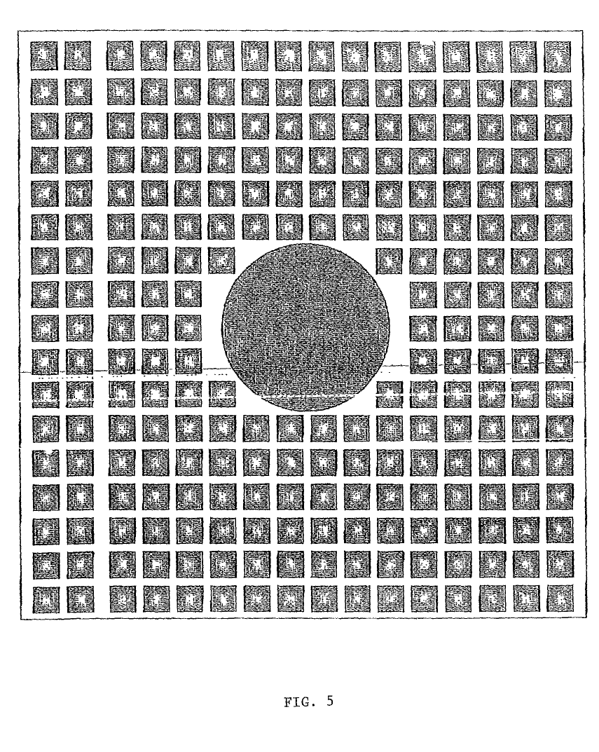

FIG. 6 is a plan view of a light-emitting surface of an LED of the invention having a patterned array of hexagonal pyramidal structures.

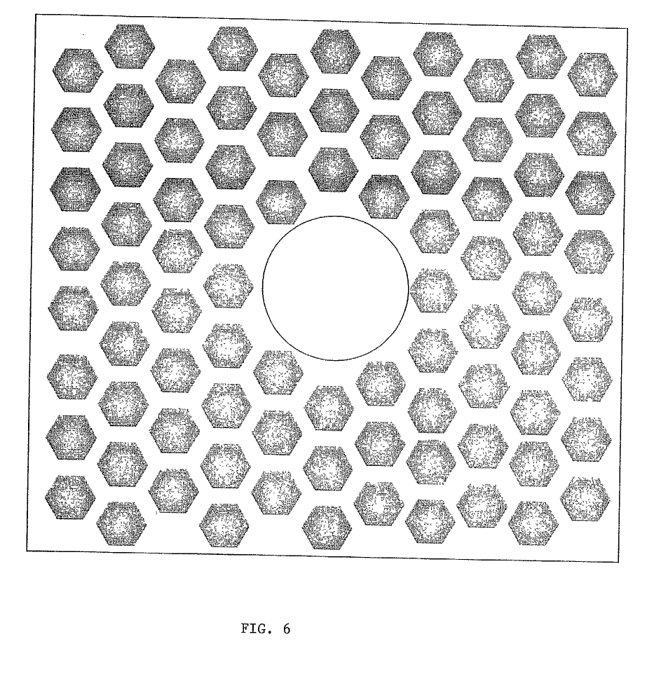

### DETAILED DESCRIPTION OF THE INVENTION

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

The present invention includes LEDs having a patterned light-emitting surface which generally results in improved photon extraction over LEDs having a flat light-emitting surface. The phrase “light-emitting surface,” as used herein, refers to a surface of the LED through which light generated within the semiconductor material of the diode is transmitted. The light-emitting surface is a surface that is in contact with another optically transmissive medium, such as air or a transparent polymer, such as an epoxy. A “patterned light-emitting surface,” as defined herein, is a surface that has a plurality of raised elements that are spaced in a non-random pattern. A patterned light-emitting surface is a surface in which the incident angle for transmission of light is varied and, thus, provides more opportunities for internally generated light to strike the surface at less than the critical angle and, thereby, be emitted from the diode. Preferably, the raised elements have curved sides. In one preferred embodiment, the raised elements on a patterned light-emitting surface are an array of hemispherical elements. In another preferred embodiment, the raised elements on a patterned light-emitting surface are an array of pyramidal elements having a square or hexagonal base. Preferably, the raised elements have a maximum width at their base in a range of between about 0.5 μm and about 20 μm. When the raised elements are an array of hemispherical surface structures, the diameter at the base of each hemisphere is about 0.5 μm to about 20 μm. When the raised elements are an array of pyramidal surface structures, the diagonal at the base of each pyramid is about 0.5 μm to about 20 μm.

In one embodiment, LEDs of the invention have an n-doped semiconductor layer in contact with a p-doped semiconductor layer and at least one patterned light-emitting surface. The patterned light-emitting surface is, for example, a light-emitting surface of the n-doped semiconductor or a light-emitting surface of the p-doped semiconductor. In an alternative embodiment, an active region separates the n-doped semiconductor layer from the p-doped semiconductor layer, such that a first surface of the active region is in contact with a first surface of the p-doped semiconductor layer and a second surface of the active region is in contact with a first surface of the n-doped semiconductor layer. In one embodiment, the active region includes a material that has a lower band-gap energy and higher refractive index than the n-doped and p-doped semiconductor layers. The larger-band-gap n-doped and p-doped semiconductor layers create potential barriers on both sides of the active region and cause carriers (i.e., holes and electrons) to be confined in the active region where they combine to emit light. Alternatively, the active region includes a single quantum-well layer and two surrounding barrier layers having a band-gap energy larger than the quantum-well layer but equal to or smaller than the n-doped and p-doped semiconductor layers. The active region includes multiple quantum-well layers and barrier layers alternately stacked. An active layer is a layer that has a band-gap which is smaller than the band-gap of both the p-doped semiconductor layer and the n-doped semiconductor layer that form the diode.

LEDs of the invention optionally include a substrate on which the n-doped and p-doped semiconductor layers that form the pn-junction of the diode are grown. When the substrate is transparent to the light emitted by the diode, a light-emitting surface of the substrate can be patterned to improve photon extraction from this surface instead of, or as well as, a surface of the one of the semiconductor layers forming the pn-junction. Examples of substrates that are transparent to visible light include sapphire, GaAs, InP and GaN. Examples of LEDs grown on transparent substrates include InGaAs on GaAs, InGaAsP on InP, and InGaN on GaN.

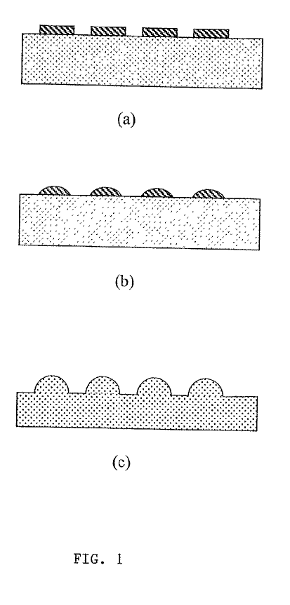

One method of forming a pattern of hemispherical structures on the surface of a substrate or semiconductor layer is shown in FIG. 1. First, an array of photoresist pattern is formed by using a standard photolithography step. Then the photoresist is heated at a high enough temperature to form rounded edges. The photoresist shape is then transferred to the semiconductor by a suitable anisotropic etching technique, such as reactive ion etching or inductively-coupled plasma. The exact shape depends on the starting photoresist shape and the etch rate ratio between the photoresist and semiconductor.

In an alternative embodiment, the substrate on which the n-doped and p-doped semiconductor layers are grown can be removed. Removal of the insulating substrate can be advantageous because it can provide a means of making electrical back-contacts on the LED or, alternatively, facilitates bonding a substrate to the LED that has more ideal thermal and electrical properties but has a surface on which the semiconductor layers that form the pn-junction of the diode do not grow well. One method of removing the substrate is a laser lift-off procedure in which the surface of a group III-nitride layer that is in contact with a transparent substrate is heated with a short laser pulse, typically about 5 ns to about 50 ns, through an optically transmissive substrate to decompose a localized surface area of the group III-nitride and, thus, separate it from the substrate. The decomposition of the material is highly localized because heat is generated quickly by the laser so that a localized high temperature is reached before the heat is conducted away from the area. This procedure takes advantage of the low decomposition temperatures of group III-nitrides, which decompose to form a group III metal and nitrogen gas. The group III metal which is deposited on the surface of the remaining group III-nitride layer is typically removed from the remaining group III-nitride layer by holding the surface over fuming HCl. The wavelength of light from the laser preferably is just above the absorption edge of the group III-nitride material to avoid degradation of the crystal quality of the remaining group III-nitride layer. For example, when the group III-nitride is GaN, the wavelength of radiation from the laser preferably is about 355 nm, which is just above the absorption edge of GaN. However, successful lift-off of GaN thin films can be performed using radiation having a wavelength of 248 nm, which is substantially above the absorption edge of GaN.

The epitaxial layers that form the pn-junction of LEDs generally are higher quality if they are grown on a substrate that has a similar crystal symmetry. However, the substrate on which a high-quality film can be grown may not have the most desirable thermal and electrical properties. For instance, silicon and GaAs have more desirable thermal and electrical properties than sapphire, but a high quality film of a group III-nitride cannot be grown on either material. Thus, group III-nitrides are generally grown on sapphire. However, this disadvantage can be overcome by removing the substrate after fabrication of the LED using, for example, the laser lift-off procedure described above, and then using a wafer bonding technique to bind a more preferred substrate to the LED.

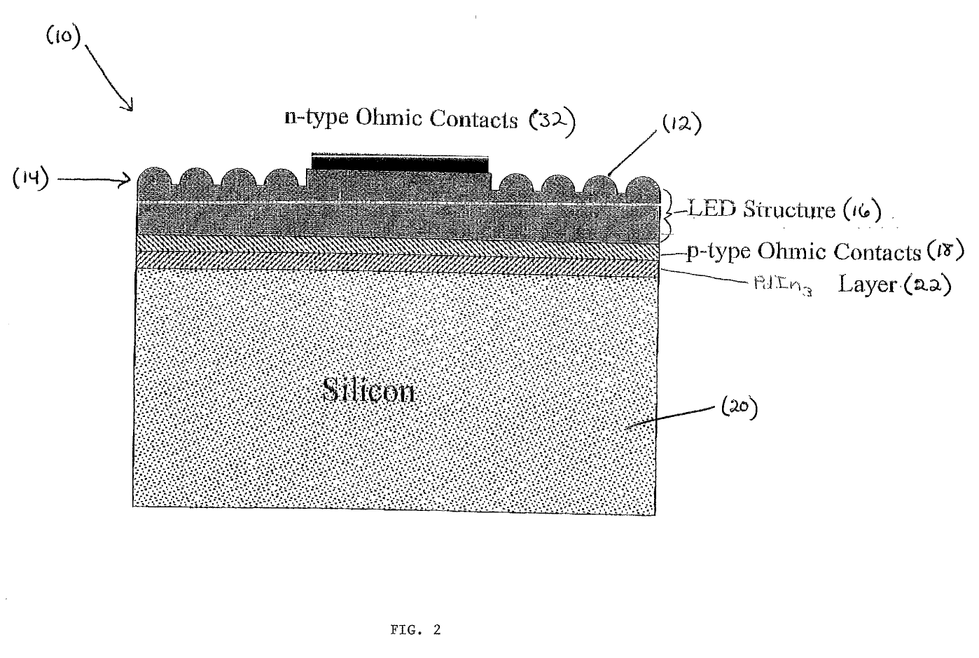

FIG. 2 is a cross-sectional view of one embodiment of a composite LED (10) having an array of hemispherical elements (12) on a light-emitting surface (14) of the LED structure (16). The LED structure (16) includes a p-doped layer in contact with an n-doped layer or a p-doped layer and an n-doped layer sandwiching an active region. The p-type ohmic contact (18) of the LED structure (16) is bound to a silicon substrate (20) through a PdIn₃ layer (22).

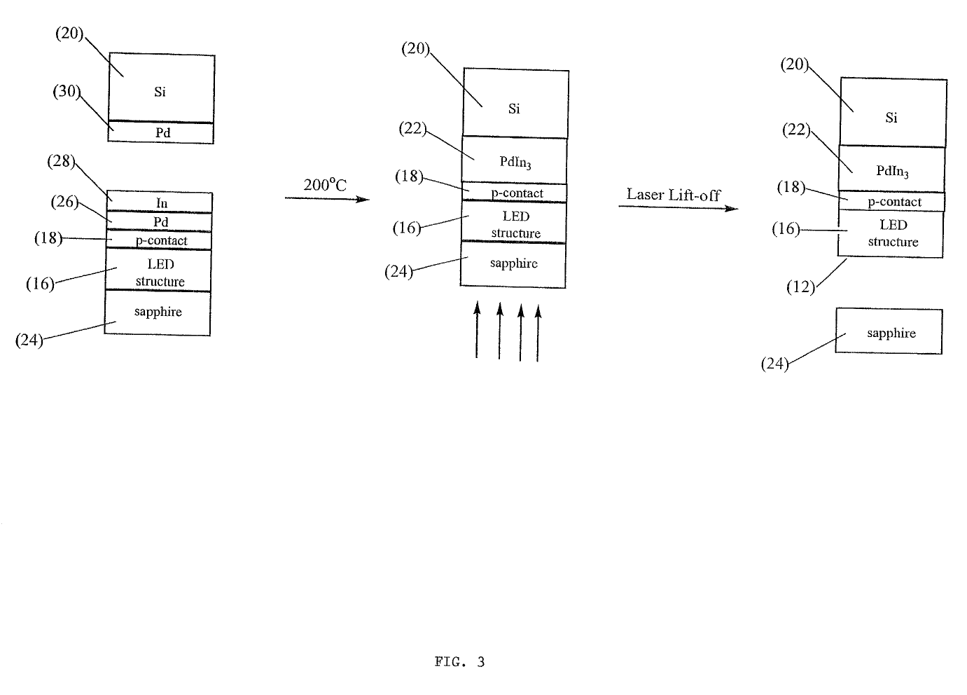

FIG. 3 is a schematic representation of steps of a method of preparing the composite LED (10) of FIG. 2. In one embodiment, an LED structure (16) of a group III-nitride is grown by metalorganic chemical vapor deposition (MOCVD) on a sapphire substrate (24). In this embodiment, an n-doped GaN layer (not shown) having a thickness of about 2 μm to about 6 μm is grown on the sapphire substrate, followed by a multi-quantum-well active region consisting of multiple InₓGa₁₋ₓN well layers having a thickness in the range of about 1 nm to about 5 nm and multiple In_{y}Ga_{1-y}N barrier layers having a thickness in the range of about 3 nm to 15 nm (not shown) in which 0<×≦1, preferably x is about 0.4, and 0≦y≦1, preferably y is less than about 0.05. A p-doped GaN layer (not shown) having a thickness of about 200 nm to about 300 nm is grown over the active region. Ni/Au metal electrodes are then deposited on the p-doped GaN layer forming the p-type ohmic contact layer (18). A Pd layer (26) having a thickness of about 50 nm to about 150 nm is deposited on the p-contacts by electron beam evaporation at a base pressure of about 1×10⁻⁷ Torr, followed by an In layer (28) having a thickness of about 0.5 μm to bout 2 μm. The In layer (28) is deposited by thermal evaporation at a base pressure of about 5×10⁻⁷ Torr. Separately, a Si substrate (20) is coated by a Pd layer (30) having a thickness of about 50 nm to about 150 nm. The In layer of the Pd-In coated LED is then placed in contact with the Pd layer of the Si substrate and bonded by applying pressure of about 2.8 MPa at a temperature of about 200° C. At this temperature, molten In is formed and reacts with Pd in a “wafer bonding reaction” to form a PdIn₃ compound that has a melting point of 664° C. Thus, the reaction is complete when a solid PdIn₃ layer (22) forms. The thickness of the Pd layers (26 and 30) and the In layer (28) are chosen such that the molar ratio of the sum of the Pd layers (26 and 30) to the In layer (28) is between about 1:1 to about 1:3 to ensure that all of the In reacts with Pd.

After the wafer bonding reaction is complete, the sapphire substrate can be removed by directing a laser through the sapphire substrate at the surface of the LED structure in contact with the substrate. This will decompose a localized surface region of the group III-nitride layer into group III metal and nitrogen gas. After removal of the group III metal with fuming HCl, the surface can be patterned by using the technique described above or other methods known to those skilled in the art.

Equivalents

While this invention has been particularly shown and described with references to preferred embodiments thereof, it will be understood by those skilled in the art that various changes in form and details may be made therein without departing from the scope of the invention encompassed by the appended claims.

What is claimed is:

1. A light-emitting diode, wherein the improvement comprises at least one patterned light-emitting surface.

2. The diode of claim 1, wherein the patterned surface includes an array of essentially hemispherical surface structures.

3. The diode of claim 2, wherein each hemisphere has a diameter at its base in the range of about 0.5 μm to about 20 μm.

4. The diode of claim 1, wherein the patterned surface includes an array of pyramidal surface structures having an essentially square base.

5. The diode of claim 4, wherein each pyramid has a diagonal at its base in the range of about 0.5 μm to about 20 μm.

6. The diode of claim 1, wherein the patterned surface includes an array of pyramidal surface structures having an essentially hexagonal base.

7. The diode of claim 6, wherein each hexagonal pyramid has a diagonal at its base in the range of about 0.5 μm to about 20 μm.

8. The diode of claim 1, wherein the patterned surface that emits light is a semiconductor surface.

9. A light-emitting diode, comprising:
a) a diode structure including:
i) an n-doped semiconductor layer in contact with a p-doped semiconductor layer; or
ii) an n-doped semiconductor layer having a first surface in contact with a first surface of an active region and a p-doped semiconductor layer having a first surface in contact with a second surface of the active region; and
b) at least one patterned light-emitting surface, whereby light emitted is transmitted through the patterned surface.

10. The diode of claim 9, wherein the patterned light-emitting surface is a surface of the n-doped semiconductor or a surface of the p-doped semiconductor.

11. The diode of claim 10, wherein the patterned light-emitting surface includes an array of essentially hemispherical surface structures.

12. The diode of claim 11, wherein each hemisphere has a diameter at its base in the range of about 0.5 μm to about 20 μm.

13. The diode of claim 10, wherein the patterned light-emitting surface includes an array of pyramidal surface structures having an essentially square base.

14. The diode of claim 13, wherein each pyramid has a diagonal at its base in the range of about 0.5 μm to about 20 μm.

15. The diode of claim 10, wherein the patterned surface includes an array of pyramidal surface structures having an essentially hexagonal base.

16. The diode of claim 15, wherein each hexagonal pyramid has a diagonal at its base in the range of about 0.5 μm to about 20 μm.

17. The diode of claim 9, wherein the p-doped semiconductor layer and the n-doped semiconductor layer are GaN and the active region has multiple quantum-well layers comprising InₓGa₁₋ₓN, wherein 0<×≦1, and multiple barrier layers comprising In_{y}Ga_{1-y}N, wherein 0≦y≦1 and y<x.

18. The diode of claim 9, further comprising a transparent substrate having a first surface and a second surface, wherein the first surface is in contact with a surface of the n-doped semiconductor layer or a surface of the p-doped semiconductor layer, and wherein the second surface of the substrate is the patterned light-emitting surface.

19. The diode of claim 18, wherein the second substrate surface includes an array of essentially hemispherical surface structures.

20. The diode of claim 19, wherein each hemisphere has a diameter at its base in the range of about 0.5 μm to about 20 μm.

21. The diode of claim 18, wherein the second substrate surface includes an array of pyramidal surface structures having an essentially square base.

22. The diode of claim 21, wherein each pyramid has a diagonal at its base in the range of about 0.5 μm to about 20 μm.

23. The diode of claim 18, wherein the patterned surface includes an array of pyramidal surface structures having an essentially hexagonal base.

24. The diode of claim 23, wherein each hexagonal pyramid has a diagonal at its base in the range of about 0.5 μm to about 20 μm.

25. The diode of claim 18, wherein the substrate includes GaAs and the n-doped and the p-doped semiconductor layers include InGaAs.

26. The diode of claim 18, wherein the substrate includes InP and the n-doped and the p-doped semiconductor layers include InGaAsP.

27. The diode of claim 18, wherein the substrate includes GaN and the n-doped and the p-doped semiconductor layers include InGaN.

28. A light-emitting diode, comprising:
a) an n-doped GaN layer having a first and a second surface, wherein the first surface emits light and is patterned;
b) a multiple quantum-well active region having a first surface in contact with the second surface of the n-doped GaN layer, wherein the multiple quantum-well active region comprises multiple InₓGa₁₋ₓN well layers, wherein 0<×≦1, and multiple In_{y}Ga_{1-y}N barrier layers, wherein 0≦y≦1 and y<x;
c) a p-doped GaN layer having a first and a second surface, wherein the first surface of the p-doped GaN layer is in contact with a second surface of the active region and the second surface is in contact with an ohmic contact layer and a light reflecting layer; and
d) a silicon, germanium, gallium arsenide or metallic substrate bound to the ohmic contact layer with an electrically-conducting bonding layer.

29. The diode of claim 28, wherein a reflective layer is between the ohmic contact layer and the bonding layer.
